(19) United States
(12) Patent Application Publication
(10) Pub. No.: US 2025/0318412 A1
(43) Pub. Date: Oct. 9, 2025

(54) DISPLAY DEVICE

(71) Applicant: Japan Display Inc., Tokyo (JP)

(72) Inventor: Junko NAGASAWA, Tokyo (JP)

(21) Appl. No.: 19/089,146

(22) Filed: Mar. 25, 2025

(30) Foreign Application Priority Data
Apr. 9, 2024 (JP) 2024-062721

(51) Int. Cl. H10K 59/80; H10K 59/122

(52) U.S. Cl. CPC H10K 59/879; H10K 59/122

(57) ABSTRACT

According to one embodiment, a display device includes a plurality of light emitting elements, a plurality of lenses that overlap the plurality of light emitting elements, and a first protective layer having a first main surface on which the plurality of lenses are disposed between the plurality of light emitting elements and the plurality of lenses. The first main surface has a pattern texture including protruding portions that protrude toward the plurality of lenses.

### CROSS-REFERENCE TO RELATED APPLICATIONS

This application is based upon and claims the benefit of priority from Japanese Patent Application No. 2024-062721, filed Apr. 9, 2024, the entire contents of which are incorporated herein by reference.

### FIELD

Embodiments described herein relate generally to a display device.

### BACKGROUND

In recent years, display devices using light-emitting elements such as organic EL elements or light-emitting diodes have been proposed. In order to extract the emitted light from these light-emitting elements more efficiently, lenses may be further provided above the light-emitting elements, respectively, in some cases.

### BRIEF DESCRIPTION OF THE DRAWINGS

FIG. 1 is a plan view schematically showing a display device according to the first embodiment.

FIG. 2 is a diagram showing an example of layout of light-emitting elements and lens subpixels.

FIG. 3 is a cross-sectional view showing a configuration example of the display device of the first embodiment

FIG. 4 is a diagram illustrating a pattern of projections and recesses.

FIG. 5 is a diagram illustrating a step in a process of manufacturing the display device.

FIG. 6 is a diagram illustrating a step in a process of manufacturing the display device.

FIG. 7 is a diagram illustrating a step in a process of manufacturing the display device.

FIG. 8 is a diagram illustrating a step in a process of manufacturing the display device.

FIG. 9 is a diagram illustrating another pattern of projections and recesses.

FIG. 10 is a diagram illustrating still another pattern of projections and recesses.

FIG. 11 is a diagram illustrating still another pattern of projections and recesses.

FIG. 12 is a cross-sectional view schematically showing a display device according to the second embodiment.

FIG. 13 is a cross-sectional view schematically showing a display device according to the third embodiment.

FIG. 14 is a cross-sectional view schematically showing a display device according to the third embodiment.

FIG. 15 is a cross-sectional view schematically showing a display device according to the fourth embodiment.

FIG. 16 is a diagram illustrating a pattern of bank layers.

FIG. 17 is a diagram illustrating another pattern of bank layers.

FIG. 18 is a cross-sectional view schematically showing a display device according to the fifth embodiment.

### DETAILED DESCRIPTION

In general, according to one embodiment, a display device comprises a plurality of light emitting elements, a plurality of lenses overlapping the plurality of light emitting elements, and a first protective layer including a first main surface on which the plurality of lenses are disposed, between the plurality of light emitting elements and the plurality of lenses. The first main surface has a pattern texture including protruding portions which protrude toward the plurality of lenses.

According to another embodiment, a display device comprises a plurality of light emitting elements, a plurality of lenses overlapping the plurality of light emitting elements, respectively, a first protective layer disposed between the plurality of light emitting elements and the plurality of lenses, and an underlying layer including a second main surface on which the plurality of lenses are disposed, between the first protective layer and the plurality of lenses. The underlying layer has at least one of a higher oil repellency and a higher water repellency than that of the first protective layer.

According to still another embodiment, a display device comprises a plurality of light emitting elements, a plurality of lenses overlapping the plurality of light emitting elements, respectively, a first protective layer including a first main surface on which the plurality of lenses are disposed between the plurality of light emitting elements and the plurality of lenses, and a bank layer disposed on the first main surface and having a refractive index equivalent to that of the plurality of lenses. The bank layer includes apertures overlapping the plurality of lenses, respectively.

With configurations such as described above, it is possible to provide a display device which can suppress the decrease in display quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course.

In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

### First Embodiment

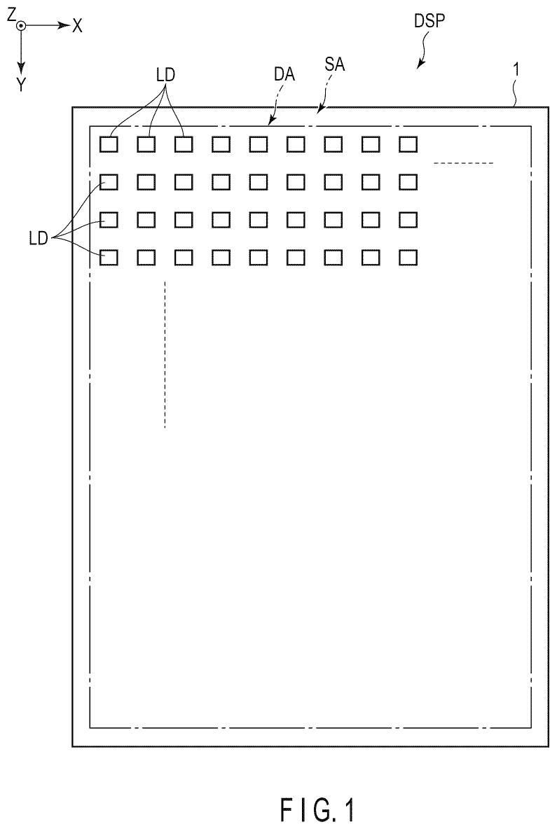

FIG. 1 is a plan view schematically showing the display device DSP according to this embodiment. The display device DSP comprises a display panel 1. The display panel 1 includes a display area DA which displays images and a frame-shaped surrounding area SA surrounding the display area DA. The display area DA and surrounding area SA are formed on an insulating substrate.

In the example shown in FIG. 1, the display panel 1 has a rectangular shape that is elongated along the second direction Y. Note here that the shape of the display panel 1 is not limited to that of this example, and it may be, for example, a rectangular shape elongated along the first direction X, a square shape, a circular shape, or an elliptical shape.

The display device DSP comprises a plurality of light emitting elements LD arranged in a matrix along the first direction X and the second direction Y. The light emitting elements LD are disposed in the display area DA. Each pair of the light emitting elements LD adjacent to each other along the first direction X or those adjacent to each other along the second direction Y are separated away from each other.

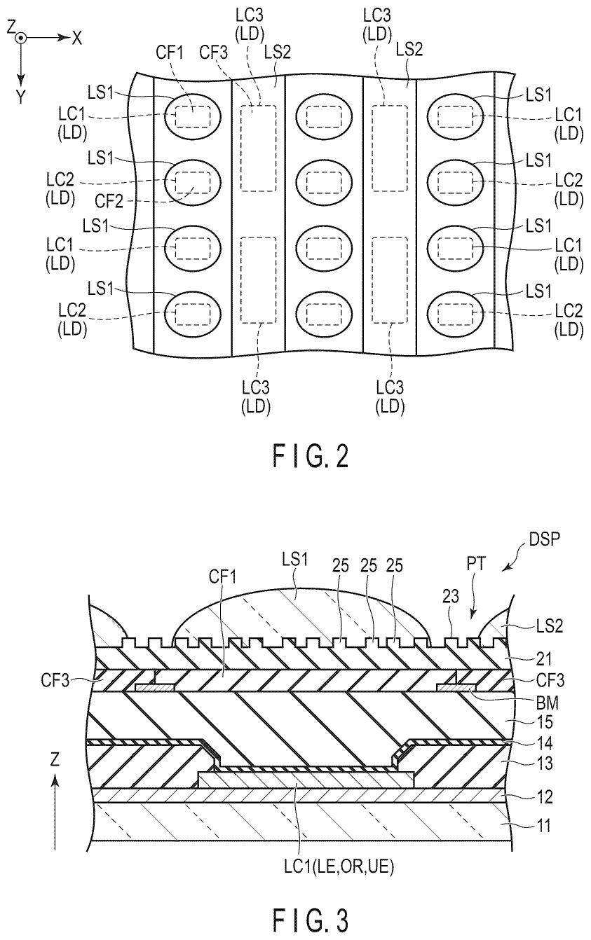

FIG. 2 is a plan view showing an example of layout of light emitting elements LD, lenses LS1 and lenses LS2. The light emitting elements LD include light emitting elements of a first color LC1, light emitting elements of a second color LC2, and light emitting elements of a third color LC3. The first color, the second color, and the third color are, for example, different from each other. For example, the first color is red, the second color is green, and the third color is blue, but the colors are not limited to the case of this example.

In the example shown in FIG. 2, the light emitting elements LC1 and light emitting elements LC2 are aligned along the second direction Y. The light emitting elements LC1 and light emitting elements LC3 are aligned along the first direction X, and the light emitting elements LC2 and light emitting elements LC3 are aligned along the first direction X.

When the light emitting elements LC1, LC2, and LC3 are arranged in such a layout, on the display area DA, there are formed rows in each of which light emitting elements LC1 and light emitting elements LC2 are disposed alternately along the second direction Y, and rows in each of which multiple light emitting elements LC3 are arranged repeatedly along the second direction Y. These rows are arranged alternately along the first direction X.

The display device DSP further comprises color filters CF1, CF2, and CF3. The color filters CF1, CF2, and CF3 are located to overlap the light emitting elements LC1, LC2, and LC3, respectively.

The display device DSP further comprises a plurality of lenses LS1 and LS2. These lenses LS1 and

LS2 may as well be referred to as micro-lenses in some cases. The lenses LS1 and LS2 have the function of changing the light irradiated from the light emitting elements LD into light directed along the third direction Z and extracting the light to outside of the display panel 1 (shown in FIG. 1).

These lenses LS1 and LS2 are convex lenses that protrude in the third direction Z. More specifically, the lenses LS1 and LS2 are aspherical lenses. The lenses LS1 have an approximately circular shape in plan view. Here, the approximately circular shape includes circular, elliptical, oblong shapes and the like. In the example shown in FIG. 2, the lenses LS1 have an elliptical shape.

One lens LS1 overlaps one light emitting element LC1, and one lens LS1 overlaps one light emitting element LC2. The light emitting elements LC1 and LC2 do not lie off from the respective lenses LS1 in plan view.

In one example, the lenses LS2 are each a cylindrical lens. In plan view, the lenses LS2 have a shape elongated along the second direction Y. One lens LS2 overlaps multiple light emitting elements LC3. In plan view, the light emitting elements LC3 do not lie off from the respective lenses LS2. The light emitting elements LC1, LC2, and LC3, the color filters CF1, CF2, and CF3, and the lenses LS1 and LS2 are arranged in this order along the third direction Z.

Next, a configuration example of the display device DSP will be explained using a cross-sectional configuration. Note that in the following configuration example, the configuration of the main part will be explained while referring to a cross-sectional diagram of the region that includes mainly one light emitting element LC1 among the multiple light emitting elements LD disposed in the display area DA.

FIG. 3 is a cross-sectional view showing a configuration example of the display device DSP of this embodiment. The display device DSP further comprises a substrate 11, a circuit layer 12, an insulating layer 13, a sealing layer 14, a resin layer 15, a light shielding layer BM, and a first protective layer 21.

The insulating substrate 11 may be glass or a resin film having flexibility. The circuit layer 12 is disposed on the substrate 11. The circuit layer 12 includes various circuits such as pixel circuits, various wiring lines such as scanning lines, signal lines, and power lines, and various insulating layers.

The light emitting elements LD are each, for example, an organic EL element (organic light-emitting diode (OLED)). Note that the light emitting elements LD is not limited to organic electroluminescent elements, and may as well be micro-LEDs or mini-LEDs.

Here, the light emitting element LC1 will be focused, but other light emitting elements LC2 and LC3 have configurations similar to that. The light emitting element LC1, which is an organic EL element, comprises a lower electrode LE, an organic layer OR, and an upper electrode UE.

The lower electrode LE is disposed on the circuit layer 12. The lower electrode LE has a multilayered body that includes, for example, a transparent layer formed of an oxide conductive material such as indium tin oxide (ITO) and a reflective layer formed of a metal material such as silver.

The organic layer OR is disposed on the lower electrode LE. The organic layer OR includes a light emitting layer, and further, various functional layers, such as a hole injection layer, a hole transport layer, an electron blocking layer, a hole blocking layer, an electron transport layer, and an electron injection layer. The upper electrode UE is disposed on the organic layer OR. The upper electrode UE is formed of, for example, a metal material such as an alloy of magnesium and silver (MgAg).

The insulating layer 13 is formed to surround part of the light emitting element LC1. The insulating layer 13 is disposed between each adjacent pair of light emitting elements LC1, LC2, and LC3. The sealing layer 14 covers the light emitting element LC1 and the insulating layer 13.

The resin layer 15 is disposed on the sealing layer 14. The resin layer 15 has the function of planarizing the unevenness caused by the light emitting element LD, the insulating layer 13 and the like. The insulating layer 13, sealing layer 14, and resin layer 15 are formed, for example, of an inorganic insulating material such as silicon nitride. Note that the resin layer 15 may include a layer formed of an organic insulating materials in addition to the layer formed of the inorganic insulating material.

The color filters CF1 and CF3 are disposed on the resin layer 15. The color filter CF1 is formed from a resin material colored red, for example, and the color filter CF3 is formed from a resin material colored blue, for example.

The color filter CF1 is disposed directly above the light emitting element LC1 along the third direction Z. The color filter CF3 is arranged directly above the light emitting element LC3, which is not shown in the figure, along the third direction Z.

The color filter CF2 (shown in FIG. 2) is located directly above the light emitting element LC2 shown in FIG. 2. The color filter CF2 is formed of a resin material colored green, for example.

Red light emitted from the light emitting element LC1, for example, passes through the color filter CF1. In contrast, blue light emitted from the light emitting element LC3 is absorbed by the color filter CF1. In this way, the mixing of colors can be suppressed, thereby making it possible to prevent degradation in display quality. Further, the color filters CF1, CF2, and CF3 can suppress the reflection of light from the outside.

The light shielding layers BM are disposed on the resin layer 15. In other words, the light shielding layers BM are each placed between the resin layer 15 and the color filters CF1 and CF3. When focusing on the color filters CF1 and CF3, the light shielding layers BM overlap peripheral portions of the color filters CF1 and CF3. Although not shown in the figure, the light shielding layer BM overlaps peripheral portions of the color filters CF1 and CF2, and peripheral portions of the color filters CF2 and CF3 as well.

When focusing on the lenses LS1 and LS2, the light shielding layer BM is located between each adjacent pair of lenses LS1 and LS2. Although not shown in the figure, the light shielding layer BM is placed between each adjacent pair of lenses LS1 as well. Note that the light shielding layer BM may overlap each respective one of the lenses LS1 and LS2 along the third direction Z.

The first protective layer 21 is disposed on the color filters CF1 and CF3. In other words, the color filters CF1, CF2, and CF3 are disposed between the light emitting elements LC1, LC2, and LC3 and the first protective layer 21.

The first protective layer 21 is, for example, a transparent organic insulating layer, and is formed, for example, of a resin material such as acrylic resin, epoxy resin, or polyimide resin. Note that the first protective layer 21 may as well be formed from some other material than these.

The first protective layer 21 has a first main surface 23 on which the plurality of lenses LS1 and LS2 are disposed. The plurality of lenses LS1 and LS2 are in contact with the first main surface 23. The first main surface 23 has a pattern texture PT.

The pattern texture PT is formed by performing half-exposure in the region where the pattern texture PT is to be formed when forming the first protective layer 21. The pattern texture PT includes a plurality of protruding portions 25. The protruding portions 25 protrude in the third direction Z toward the lenses LS1 and LS2, respectively.

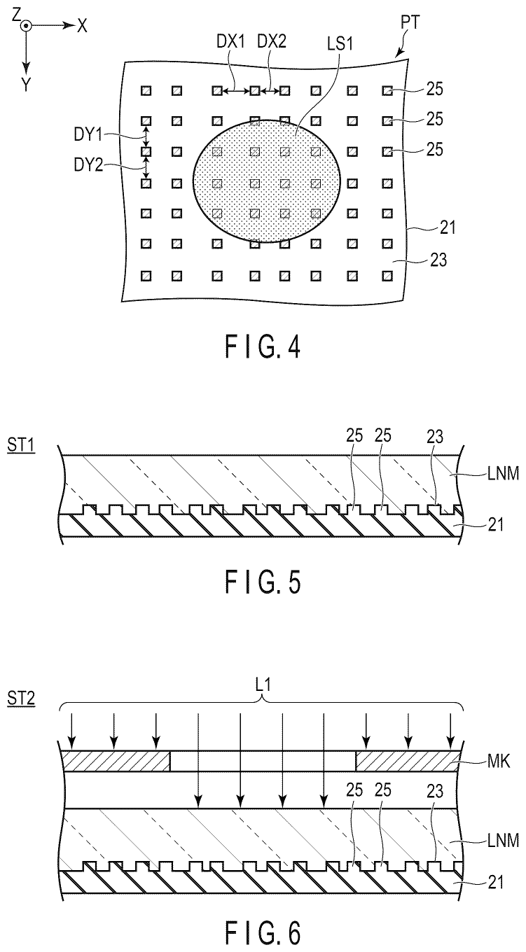

Here, an example of the pattern texture PT will be explained with reference to FIG. 4. FIG. 4 is a diagram for illustrating the pattern texture PT. In FIG. 4, only the lens LS1 of the lenses LS1, LS2, LS3 is shown. In the example shown in FIG. 4, the pattern texture PT is formed in a dot-like manner by the multiple protruding portions 25 in plan view. The lens LS1 overlaps multiple protruding portions 25. The shape of the protruding portions 25 is square in plan view here, but it may as well be a polygon, circle, or ellipse. The size of the protruding portions 25 should preferably be as small as possible.

Next, the distance between an adjacent pair of protruding portions 25 will be explained with reference to FIG. 4. As shown in FIG. 4, distances between respective pairs of protruding portions 25 adjacent to each other along the first direction X are defined as a distance DX1 and a distance DX2, and distances between respective pairs of protruding portions 25 adjacent to each other along the second direction Y are defined as a distance DY1 and a distance DY2.

When focusing on the distances DX1 and DX2 and the distances DY1 and DY2 in protruding portions 25, for example, the distance DX1 is different from the distance DX2, and the distance DY1 is different from the distance DY2. Note here that the distances between adjacent protruding portions 25 may all be equal, or some may be equal while others may be different.

The lenses LS1 and LS2 are disposed on the pattern texture PT of the first protective layer 21, as shown in FIG. 3. In other words, the first protective layer 21 is arranged between the plurality of light emitting elements LD and the plurality of lenses LS1 and LS2.

Some of the lenses LS1 and LS2 are located between protruding portions 25 adjacent to each other. The first main surface 23 of the first protective layer 21 is exposed between each adjacent pair of the lenses LS1 and LS2. The lenses LS1 and LS2 are formed, for example, from a transparent resin material. When focusing on the refractive index, the refractive index of the lenses LS1 and LS2 is higher than the refractive index of the first protective layer 21. For example, when the refractive index of the first protective layer 21 is 1.5, the refractive index of the lenses LS1 and LS2 is higher than 1.5.

Next, with reference to FIGS. 5 to 8, the manufacturing process of the lenses LS1, which is part of the manufacturing process of the display device DSP, will be explained. FIGS. 5 to 8 are diagrams for illustrating the manufacturing process of the display device DSP. Here, the process for the lens LS1 will be explained as an example, but the lens LS2 is formed in a similar manner.

First, as shown in FIG. 5, a lens material LNM for forming the lens LS1 is applied onto the first protective layer 21 (first step ST1). The lens material LNM is, for example, a negative-type resin material.

After the first processing step ST1, a mask MK with an aperture having a predetermined shape is placed on the lens material LNM as shown in FIG. 6. Then, light L1 is irradiated through the mask MK to expose the lens material LNM (second step ST2). The light L1 is, for example, ultraviolet light.

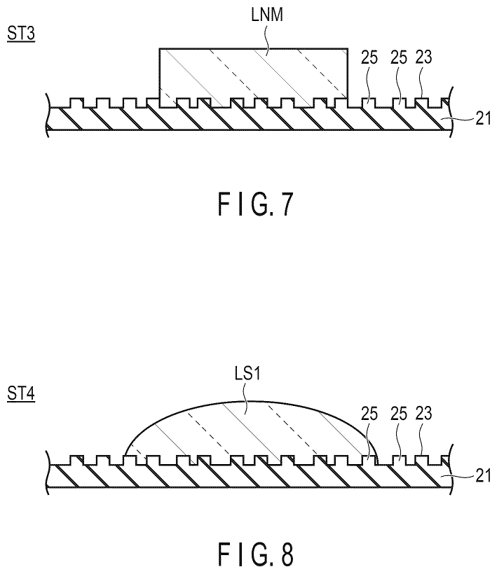

After the second processing step (ST2), the lens material LNM is developed (third step (ST3)), as shown in FIG. 7. In the example shown in FIG. 7, the region of the lens material LNM, which has been exposed to the light L1 remains, and the region shielded from light by the mask MK is removed.

Next, as shown in FIG. 8, the remaining lens material LNM is sintered (fourth step (ST4)). In Step 4, when the lens material LNM is made to reflow, the reflowing material is formed into a convex lens shape due to surface tension, and then it hardens in the state to form the lens LS1.

When the lens material LNM spreads over on the first main surface 23 more than necessary in the fourth step ST 4, it becomes difficult to stably manufacture the lens LS1 with the desired shape. As a result, it becomes difficult to obtain a lens with the desired optical performance.

Further, when the display device DSP is of the high-definition, the light emitting elements LD become smaller (for example, the width is 6 μm or less), and the distance between each adjacent pair of light emitting elements LD also becomes smaller. Therefore, when reflowing, there is a risk that adjacent lens materials LNM will connect with each other.

In this embodiment, the lenses LS1 and LS2 are disposed on the pattern texture PT of the first main surface 23 of the first protective layer 21. More specifically, the lenses LS1 and LS2 are each overlaid on multiple protruding portions 25 that form the pattern texture PT.

When reflowing, these multiple protruding portions 25 can suppress the lens material LNM from spreading over the first main surface 23 more than necessary. For example, as air enters between adjacent protruding portions 25, the spreading can be suppressed. In this manner, it is possible to suppress lens materials LNM located adjacent to each other from connecting with each other.

Thus, when the spreading of the lens material LNM is suppresses, and the lenses LS1 and LS2 having the desired shape can be stably manufactured. In other words, it is possible to manufacture lenses LS1 and LS2 having the desired optical performance.

As a result, it is possible to suppress the decrease in the extraction efficiency of the light irradiated from the light emitting element LD and to improve the luminance, thereby suppressing the decrease in the display quality of the display device DSP. In addition, various other advantageous effects can be obtained from this embodiment.

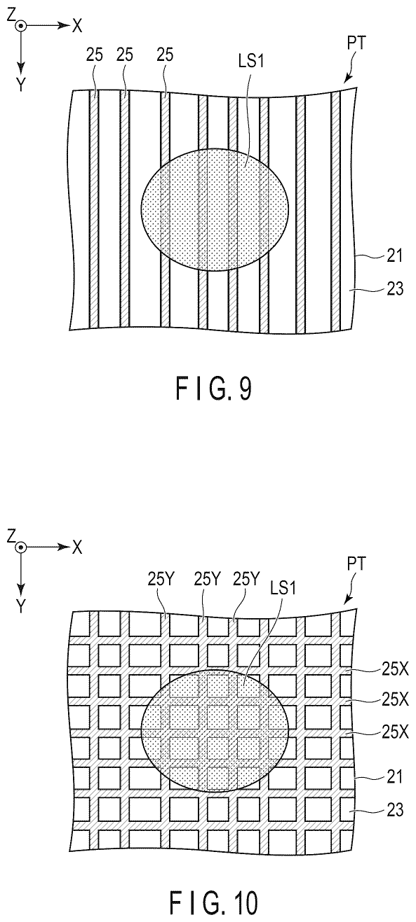

Note that in this embodiment, an example in which the pattern texture PT is formed in the shape of dots is explained, but the pattern texture PT is not limited to that of this example. FIGS. 9 to 11 are diagrams for illustrating other examples of the pattern texture PT. In FIGS. 9 to 11, only one of the multiple lenses LS1 and LS2 is shown.

In the example shown in FIG. 9, the pattern texture PT is formed into a striped pattern by multiple protruding portions 25 in plan view. The multiple protruding portions 25 extend along the second direction Y and are aligned along the first direction X. Note that the multiple protruding portions 25 may as well be formed such as to extend along the first direction X and are aligned along the second direction Y. The lenses LS1 overlaps multiple protruding portions 25.

In this case, it is preferable to arrange the multiple protruding portions 25 along a direction that is orthogonal to the direction in which reflow is not desired. For example, if the direction in which reflow is not desired is the first direction X, the multiple protruding portions 25 should be arranged so as to extend along the second direction Y.

In the example shown in FIG. 10, the pattern texture PT is formed into a grid pattern by the multiple protruding portions 25 in plan view. Specifically, the plurality of protruding portions 25 include multiple first portions 25X that extend along the first direction X and are aligned along the second direction Y, and multiple second portions 25Y that extend along the second direction Y and are aligned along the first direction X. The lenses LS1 each overlap multiple first portions 25X and multiple second portions 25Y.

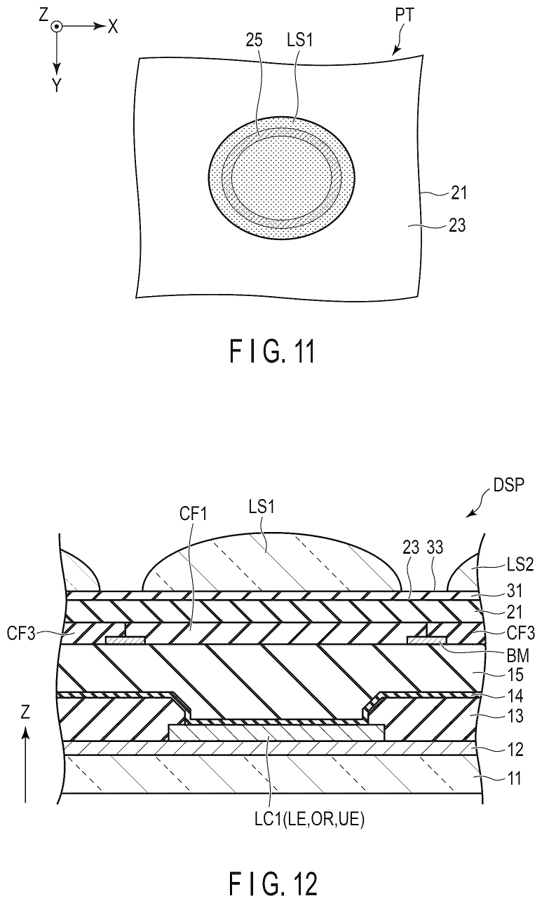

In the example shown in FIG. 11, the pattern texture PT is formed by multiple annular protruding portions 25 in plan view. In FIG. 11, one of the multiple protruding portions 25 is shown. In the example shown in FIG. 11, the protruding portions 25 have an elliptical shape as in the case of the shape of the lenses LS1.

Note that the shape of the protruding portions 25 in plan view may be circular or polygonal. Focusing on the lens LS1, one protruding portion 25 overlaps one lens LS1. The external shape of the protruding portion 25 is smaller than the external shape of the lens LS1.

In the pattern texture PT explained with reference to FIGS. 9 to 11 as well, the protruding portions 25 can suppress the lens material LNM from spreading over the first main surface 23 when the lens material LNM reflows as in the case shown in FIG. 4.

In this embodiment, an example in which the lenses LS1 and LS2 are aspherical lenses is explained, but the embodiment is not limited to this example, and a similar configuration can also be applied to lenses other than these types.

In this embodiment, an example in which the display device DSP comprises color filters CF1, CF2, and CF3 and light shielding layers BM is explained, but the display device DSP may not have at least one group of the color filters CF1, CF2, and CF3 and the light shielding layers BM. Further, the display device DSP may further comprise a light shielding layer between the color filters CF1, CF2, and CF3 and the lenses LS1 and LS2, respectively.

In this embodiment, an example in which the first protective layer 21 is formed from a single material is disclosed, but the embodiment is not limited to this example. The first main surface 23 may have a pattern texture (PT) formed by multiple protruding portions 25 formed from a material different from that in contact with the color filters CF1, CF2, and CF3.

The multiple protruding portions 25 are formed of, for example, a silicon oxide or the like. When the multiple protruding portions 25 are formed of such a material, the size of the multiple protruding portions 25 can be made further smaller. For example, the distance between each adjacent pair of protruding portions 25 can be made 1 μm or less, and the length of the protruding portions 25 along the third direction Z can be made 1 μm or less.

Next, other embodiments will be described. In the other embodiments provided below, structural components similar to those used in the first embodiment are denoted by the same reference symbols as used for those in the first embodiment, and in some cases, the detailed explanations therefor are omitted or simplified.

### Second Embodiment

FIG. 12 is a cross-sectional view schematically showing the display device DSP of this embodiment. This embodiment is different from the first embodiment in that the display device DSP further comprises an underlying layer 31.

The display device DSP comprises an underlying layer 31 disposed on the first protective layer 21. From another perspective, the underlying layer 31 is disposed between the first protective layer 21 and the plurality of lenses LS1 and LS2.

The underlying layer 31 has a second main surface 33 on which the plurality of lenses LS1 and LS2 are disposed. The plurality of lenses LS1 and LS2 are in contact with the second main surface 33. The second main surface 33 corresponds to a surface on an opposite side to the surface opposing the first main surface 23 of the first protective layer 21. In this embodiment, the first main surface 23 and the second main surface 33 are flat surfaces.

The second main surface 33 has at least one of oil repellency and water repellency. Specifically, the second main surface 33 has at least one of oil repellency higher than that of the first main surface 23 of the first protective layer 21 and water repellency higher than that of the first main surface 23 of the first protective layer 21.

It suffices if the second main surface 33 has an oil repellency higher than that of the first main surface 23 of the first protective layer 21, and it may have both an oil repellency higher than that of the first main surface 23 of the first protective layer 21 and a water repellency higher than that of the first main surface 23 of the first protective layer 21. The underlying layer 31 is formed of a fluorine-based organic compound or silicon oxide.

In terms of refractive index, the refractive index of the underlying layer 31 is equivalent to the refractive index of the first protective layer 21. Here, the term “equivalent” does not only mean that the difference in refractive index is zero, but also includes cases where the difference in refractive index is 0.1 or less. From another perspective, the refractive indexes of the lenses LS1 and LS2 are higher than the refractive index of the underlying layer 31.

With the configuration of this embodiment, advantageous effects similar to those of the first embodiment can be obtained. In this embodiment, the plurality of lenses LS1 and LS2 are disposed on the underlying layer 31.

For example, when the lens material LNM is placed on a layer formed of a lipophilic material (for example, acrylic resin), the contact angle with the layer decreases during reflow, and the lens material LNM is likely to spread.

In contrast, according to this embodiment, the underlying layer 31 has a higher oil repellency or a higher water repellency than that of the first protective layer 21. With this configuration, the contact angle with the second main surface 33 can be increased when reflowing, thereby making it difficult for the lens material LNM to spread. As a result, it is possible to stably manufacture lenses LS1 and LS2 with the desired shape.

### Third Embodiment

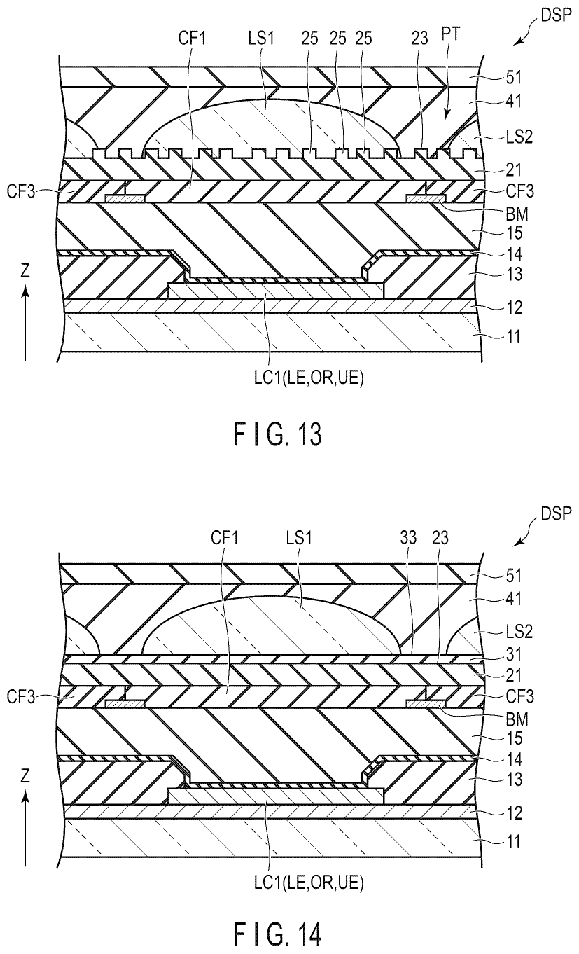

FIGS. 13 and 14 are each a cross-sectional view schematically showing the display device DSP in this embodiment. This embodiment is different from the embodiments provided above in that the display device DSP further comprises a second protective layer 41.

The display device DSP further has a second protective layer 41. The second protective layer 41 has the function of planarizing the unevenness caused by the plurality of lenses LS1 and LS2.

In the example shown in FIG. 13, the second protective layer 41 covers the plurality of lenses LS1 and LS2 and the first protective layer 21. In other words, the plurality of lenses LS1 and LS2 and the first protective layer 21 are not exposed from the second protective layer 41.

In the example shown in FIG. 14, the second protective layer 41 covers the plurality of lenses LS1 and LS2 and the underlying layer 31. In other words, the plurality of lenses LS1 and LS2 and the underlying layer 31 are not exposed from the second protective layer 41. The second protective layer 41 includes portions that are in contact with the first protective layer 21 as shown in FIGS. 13 and 14. For example, in FIG. 13, the portions of the second protective layer 41 are each located between each respective adjacent pair of protruding portions 25.

In terms of refractive index, the refractive index of the second protective layer 41 is lower than those that of the lenses LS1 and LS2, the first protective layer 21 and the second protective layer 41. The second protective layer 41 is a transparent organic insulating layer, and is formed from, for example, a resin material such as acrylic resin, epoxy resin, or polyimide resin.

The display device DSP may further comprise an optical film 51, as shown in FIGS. 13 and 14. The optical film 51 covers the second protective layer 41. The optical film 51 is, for example, a polarizer, but the configuration is not limited to that of this example.

With the configuration of this embodiment, advantageous effects similar to those of the above-provided embodiments can be obtained. In this embodiment, the display device DSP comprises the second protective layer 41. With this configuration, the lenses LS1 and LS2 can be protected from external impacts and the like.

### Fourth Embodiment

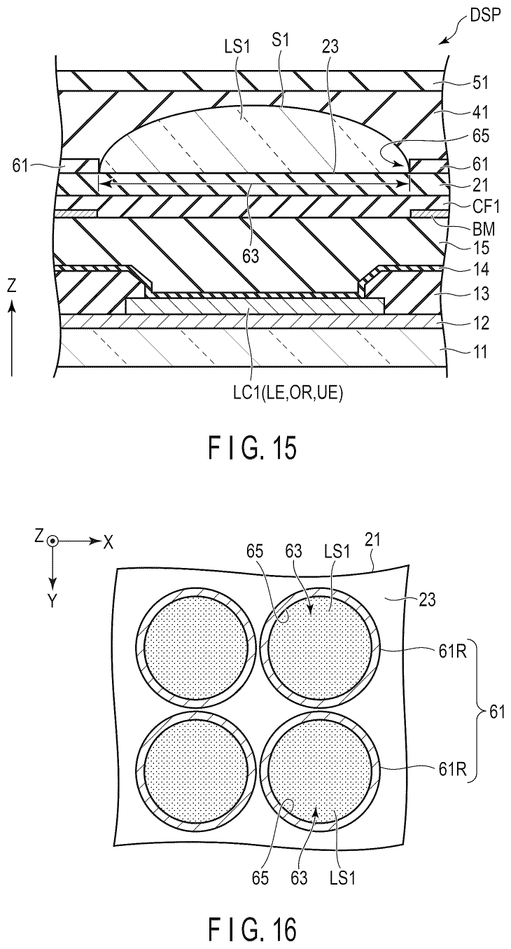

FIG. 15 is a cross-sectional view schematically showing the display device DSP according to this embodiment. This embodiment is different from the first embodiment in that the display device DSP comprises a bank layer 61.

The display device DSP comprises a bank layer 61 disposed on the first main surface 23 of the first protective layer 21. The first main surface 23 in this embodiment is a flat surface.

The bank layer 61 has an aperture 63 that overlaps the lens LS1. In other words, the lens LS1 is disposed on the first main surface 23 of the first protective layer 21. The aperture 63 penetrates the bank layer 61. In the third direction Z, the bank layer 61 does not overlap the lens LS1.

The bank layer 61 has a circumferential surface 65 that defines the aperture 63. The circumferential surface 65 surrounds the lens LS1. The circumferential surface 65 opposes the surface S1 of the lens LS1, which is an aspherical surface. In the example shown in FIG. 15, the circumferential surface 65 is in contact with the surface S1, but the circumferential surface 65 may be separated away from the surface S1.

The thickness of the bank layer 61 is, for example, less than or equal to half the thickness of the lens LS1. For example, if the thickness of lens LS1 is 3 μm, the thickness of bank layer 61 is 1 μm, for example.

The bank layer 61 is formed of a material having a refractive index equivalent to that of the lens LS1. The bank layer 61 is formed of silicon nitride, for example. The second protective layer 41 the covers lens LS1 and the bank layer 61. The optical film 51 is disposed on the second protective layer 41.

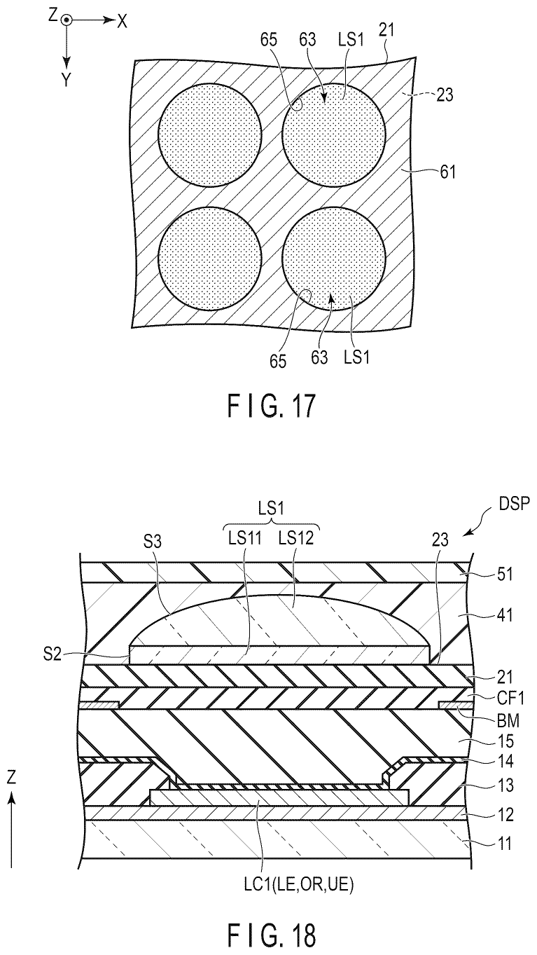

Here, an example of the pattern of the bank layer 61 will be explained with reference to FIGS. 16 and 17. FIGS. 16 and 17 are diagrams used to illustrate the pattern of the bank layer 61. In the example shown in FIGS. 16 and 17, a plurality of lenses LS1 are aligned along the first direction X and the second direction Y, but the bank layer 61 can be applied to the lenses LS2 as well.

The bank layer 61 is formed by multiple rings 61R, as shown in FIG. 16. The shape of the rings 61R in plan view is larger than the shape of the lenses LS1 in plan view. The shape of the rings 61R is changed as appropriate according to the shape of the lenses LS1.

The bank layer 61 covers the first protective layer 21, as shown in FIG. 17. In this case, the bank layer 61 covers the gaps between lenses LS1 adjacent to each other, and thus the first protective layer 21 is not exposed from the bank layer 61.

With the configuration of this embodiment, advantageous effects similar to those of the first embodiment can be obtained. In this embodiment, the display device DSP comprises the bank layer 61. With this configuration, the lens material LNM can be prevented from spreading by the aperture 63 in the fourth manufacturing step ST4.

### Fifth Embodiment

FIG. 18 is a cross-sectional view schematically showing the display device DSP according to this embodiment. This embodiment is different from the first embodiment in the configuration of the lens. Here, the configuration will be explained while focusing on the lenses LS1, but the configuration can be applied to the lenses LS2 as well.

The lens LS1 is disposed on the first main surface 23 of the first protective layer 21. In this embodiment, the first main surface 23 is a flat surface. The lens LS1 includes a first lens portion LS11 located on the first main surface 23 and a second lens portion LS12 located on the first lens portion LS11. The first lens portion LS11 is formed of a material that is different from that of the second lens portion LS12.

As shown in FIG. 18, the first lens portion LS11 has a square shape, and the second lens portion LS12 has a convex shape. The first lens portion LS11 is formed from a material that is more difficult to reflow than the second lens portion LS12. The first lens portion LS11 is formed of acrylic resin, for example. The first lens portion LS11 has a refractive index equivalent to that of the second lens portion LS12.

The second protective layer 41 covers a side surface S2 of the first lens portion LS11 and a surface S3 of the second lens portion LS12. The optical film 51 is disposed on the second protective layer 41.

With the configuration of this embodiment, advantageous effects similar to those of the first embodiment can be obtained. In this embodiment, the lens LS1 includes the first lens portion LS11 and the second lens portion LS12. With this configuration, the material to form the second lens portion LS12 can be prevented from spreading beyond the size of the first lens portion LS11 when reflowing in the fourth step ST4 of the manufacturing process.

Note that in the present embodiment and the fourth embodiment, the display device DSP comprises the second protective layer 41 and the optical film 51, but the display device DSP in these embodiments may not necessarily include a second protective layer 41 and an optical film 51.

Based on the display devices described above as embodiments of the invention, a person having ordinary skill in the art may achieve display devices with arbitral design changes; however, as long as they fall within the scope and spirit of the present invention, all of such display devices are encompassed by the scope of the present invention. A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
a plurality of light emitting elements;
a plurality of lenses overlapping the plurality of light emitting elements; and
a first protective layer including a first main surface on which the plurality of lenses are disposed, between the plurality of light emitting elements and the plurality of lenses,
wherein
the first main surface has a pattern texture including protruding portions which protrude toward the plurality of lenses.

2. The display device of claim 1, wherein
a part of each of the plurality of lenses is located between each respective adjacent pair of the plurality of protruding portion.

3. The display device of claim 1, wherein
the pattern texture is formed into a dot-like manner by the plurality of protruding portions in plan view.

4. The display device of claim 1, wherein
the pattern texture is formed in a shape of stripes by the plurality of protruding portions in plan view.

5. The display device of claim 1, therein
the pattern texture is formed into a grid pattern by the plurality of protruding portions in plan view.

6. The display device of claim 1, wherein
the pattern texture is formed by the plurality of protruding portions having a ring-like shape in plan view.

7. A display device comprising:
a plurality of light emitting elements;
a plurality of lenses overlapping the plurality of light emitting elements, respectively;
a first protective layer disposed between the plurality of light emitting elements and the plurality of lenses; and
an underlying layer including a second main surface on which the plurality of lenses are disposed, between the first protective layer and the plurality of lenses,
wherein
the underlying layer has at least one of a higher oil repellency and a higher water repellency than that of the first protective layer.

8. The display device of claim 7, wherein
the underlying layer is formed of a fluorine-based organic compound or silicon oxide.

9. The display device of claim 7, wherein
the underlying layer has a refractive index equivalent to a refractive index of the first protective layer.

10. The display device of claim 9, wherein
the refractive index of the plurality of lenses is higher than the refractive index of the underlying layer.

11. A display device comprising:
a plurality of light emitting elements;
a plurality of lenses overlapping the plurality of light emitting elements, respectively;
a first protective layer including a first main surface on which the plurality of lenses are disposed between the plurality of light emitting elements and the plurality of lenses; and
a bank layer disposed on the first main surface and having a refractive index equivalent to that of the plurality of lenses,
wherein
the bank layer includes apertures overlapping the plurality of lenses, respectively.

12. The display device of claim 11, wherein
the bank layer is constituted by a plurality of rings each including the aperture.

13. The display device of claim 11, wherein the bank layer covers the first protective layer.

14. The display device of claim 1, further comprising:
a second protective layer that covers the plurality of lenses and has a refractive index lower than that of the plurality of lenses.

15. The display device of claim 14, further comprising:
an optical film disposed on the second protective layer.

16. The display device of claim 1, wherein
the plurality of lenses are aspherical lenses.

17. The display device of claim 1, further comprising:
a color filter disposed between the light emitting elements and the first protective layer and overlapping the plurality of light emitting elements.

18. The display device of claim 1, further comprising:
a light shielding layer disposed between each adjacent pair of the plurality of lenses.

19. The display device of claim 1, wherein
the light emitting elements are organic EL elements or LEDs.
